(19) United States
(12) Patent Application Publication
(10) Pub. No.: US 2012/0159274 A1
(43) Pub. Date: Jun. 21, 2012

(54) APPARATUS TO FACILITATE BUILT-IN SELF-TEST DATA COLLECTION

(76) Inventors: Kedarnath J. Balakrishnan, Austin, TX (US); Grady Giles, Dripping Springs, TX (US); Tim Wood, Austin, TX (US); Eswar Vadlamani, Bangalore (IN)

(21) Appl. No.: 12/975,342

(22) Filed: Dec. 21, 2010

(51) Int. Cl. G01R 31/3177; G06F 11/25

(52) U.S. Cl. 714/732; 714/E11.155

(57) ABSTRACT

Techniques are disclosed relating to testing logic in integrated circuits using an external test tool. In one embodiment, an integrated circuit includes a logic unit and a self-test unit. The self-test unit is configured to receive an expected signature value that corresponds to an expected output value of the logic unit, and to compare the expected signature value and an actual signature value generated from an actual output value from the logic unit. In some embodiments, the integrated circuit further includes a pseudo-random pattern generator configured to provide an input value to the logic unit, and the logic unit is configured to generate the actual output value based on the provided input value. In some embodiments, the integrated circuit further includes a multiple-input signature register (MISR) configured to generate the actual signature value based on the actual output value and a seed value.

### BACKGROUND

1. Technical Field

This disclosure relates to integrated circuits, and, more specifically, to built-in self-test units.

2. Description of the Related Art

Chip developers typically perform a variety of tests on integrated circuits after fabrication to verify the integrity of those circuits. To facilitate testing, integrated circuits may include built-in self-test units that are configured to test portions of logic. Built-in self-test units may be connected to automated test equipment (ATE) that provides inputs for various tests and analyzes the resultant outputs to determine whether problems exist. Minimizing the amount of time spent testing and identifying problems is important because significant numbers of integrated circuits are typically being tested simultaneously using limited ATE resources.

### SUMMARY OF EMBODIMENTS

The present disclosure describes various embodiments of methods and structures to test logic in integrated circuits using an external test tool.

In one embodiment, an integrated circuit is disclosed. The integrated circuit includes a logic unit and a self-test unit. The self-test unit is configured to receive, from a test tool external to the integrated circuit, an expected signature value that corresponds to an expected output value of the logic unit. The self-test unit is further configured to compare the expected signature value with an actual signature value generated from an actual output value of the logic unit. In various embodiments, the integrated circuit further includes a multiple-input signature register (MISR) configured to generate the actual signature value based on the actual output value and a seed value. In some embodiments, the self-test unit is configured to receive the seed value from an external test tool. The seed value is an expected signature value corresponding to a previous expected output value.

In one embodiment, a computer readable storage medium is disclosed. The computer readable storage medium has program instructions stored thereon. The program instructions are executable by a computer system to cause the computer system to perform providing an expected signature value to a self-test unit on an integrated circuit. The expected signature value corresponds to an expected output value of a logic unit on the integrated circuit, and the self-test unit is configured to perform a comparison of the expected signature value with an actual signature value generated from an actual output value of the logic unit. The program instructions are further executable to cause performance of receiving a result of the comparison from the self-test unit.

In one embodiment, a method is disclosed. The method includes a test unit in an integrated circuit receiving an expected signature value from a test tool external to the integrated circuit. The expected signature value corresponds to an expected output value of a logic unit in the integrated circuit. The method further includes the test unit comparing the expected signature value with a first actual signature value generated from an actual output value of the logic unit. The method further includes the test unit providing a result of the comparison to the external test tool.

In one embodiment, a computer readable storage medium is disclosed. The computer readable storage medium includes a data structure which is operated upon by a program executable on a computer system, the program operating on the data structure to perform a portion of a process to fabricate an integrated circuit including circuitry described by the data structure. The circuitry described by the data structure includes a self-test unit configured to receive an expected signature value that corresponds to an expected output value of a logic unit in the integrated circuit. The self-test unit is further configured to compare the expected signature value with an actual signature value generated from an actual output value of the logic unit.

### BRIEF DESCRIPTION OF THE DRAWINGS

FIG. 1 is a block diagram illustrating one embodiment of a testing system configured to test the integrity of an integrated circuit.

FIG. 2 is a block diagram illustrating one embodiment of a logic unit and a built-in self-test unit included in the integrated circuit.

FIG. 3 is a block diagram illustrating one embodiment of a debug unit included in the built-in self-test unit.

FIG. 4 is a block diagram illustrating one embodiment of a comparison unit.

FIG. 5 illustrates two exemplary timing diagrams for the built-in self-test unit.

FIG. 6 is a flow diagram illustrating one embodiment of a method performed by the built-in self-test unit.

FIG. 7 is a flow diagram illustrating one embodiment of a method performed by test equipment coupled to the built-in self-test unit.

FIG. 8 is a block diagram illustrating one embodiment of an exemplary computer system.

### DETAILED DESCRIPTION

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps. Consider a claim that recites: “An apparatus comprising one or more processor units . . . .” Such a claim does not foreclose the apparatus from including additional components (e.g., a network interface unit, graphics circuitry, etc.).

“Configured To.” Various units, circuits, or other components may be described or claimed as “configured to” perform a task or tasks. In such contexts, “configured to” is used to connote structure by indicating that the units/circuits/components include structure (e.g., circuitry) that performs those task or tasks during operation. As such, the unit/circuit/component can be said to be configured to perform the task even when the specified unit/circuit/component is not currently operational (e.g., is not on). The units/circuits/components used with the “configured to” language include hardware—for example, circuits, memory storing program instructions executable to implement the operation, etc. Reciting that a unit/circuit/component is “configured to” perform one or more tasks is expressly intended not to invoke 35 U.S.C. §112, sixth paragraph, for that unit/circuit/component. Additionally, “configured to” can include generic structure (e.g., generic circuitry) that is manipulated by software and/or firmware (e.g., an FPGA or a general-purpose processor executing software) to operate in manner that is capable of performing the task(s) at issue.

“First,” “Second,” etc. As used herein, these terms are used as labels for nouns that they precede, and do not imply any type of ordering (e.g., spatial, temporal, logical, etc.). For example, in a processor having eight processing elements or cores, the terms “first” and “second” processing elements can be used to refer to any two of the eight processing elements. In other words, the “first” and “second” processing elements are not limited to logical processing elements 0 and 1.

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

“Processor.” This term has its ordinary and accepted meaning in the art, and includes a device that is capable of executing instructions. A processor may refer, without limitation, to a central processing unit (CPU), a co-processor, an arithmetic processing unit, a graphics processing unit, a digital signal processor (DSP), etc. A processor may be a superscalar processor with a single or multiple pipelines. A processor may include a single or multiple cores that are each configured to execute instructions.

“Signature.” This term has its ordinary and accepted meaning in the art, and includes a value that is generated by applying a function to one or more values. In many instances, a signature may be a value that is smaller than the values from which it is generated. For example, a hash value may be considered as a type of signature. In various embodiments described below, a signature may be generated by circuitry (such as a multiple-input shift register (MISR) from output values produced by logic in an integrated circuit.

“Expected Output Value.” As used herein, this term refers to a value that is a correct output from logic for a given input value if logic is operating as intended (i.e., functioning properly).

“Actual Output Value.” As used herein, this term refers to a value that is output from logic for a given input value. An actual output value may be an expected output value if logic is operating as intended, or may be an unexpected value (i.e., an incorrect value) if logic is not operating as intended.

“Expected Signature.” As used herein, this term refers to a signature that is generated based on one or more expected output values. An “expected signature” may also be referred to as a correct signature or a golden signature.

“Actual Signature.” As used herein, this term refers to a signature that is generated based on one or more actual output values. Accordingly, an actual signature is equivalent to an expected signature if logic is operating as intended. An actual signature may not be equivalent to an expected signature if logic is not operating as intended.

The present disclosure describes various techniques for testing integrated circuits. Such techniques may reduce the amount of time for testing integrated circuits and thus the overall production costs of those circuits. As will be described below, an integrated circuit may include a self-test unit (e.g., a built-in self-test (BIST) unit) that tests the integrity of logic that is present in the circuit. To test the logic, the BIST may provide a set of input values to the logic to cause it to generate a corresponding set of output values. These actual output values may then be compared with the expected output values for the logic to ensure that it is operating as designed. For example, logic on an integrated circuit may be designed to produce the output value 101010 (note that the values in this example are arbitrary and merely used for illustration purposes) in response to receiving an input value 111111. To ensure that the logic correctly produces this expected output value and thus is operating as designed, a BIST may provide the input value 111111 to the logic during testing. If the logic's actual output value is 101010 and thus is the expected value, the logic is operating as designed. The logic's actual output value, however, may not match the expected value if the logic is functioning incorrectly (e.g., the actual output value may be 111010 instead of the expected output value of 101010). This mismatch may occur due to flaws in integrated circuit silicon, flaws in the fabrication process, flaws in the logic's design, etc.

Instead of directly comparing the actual output values of logic with its expected output values, a comparison of signatures may be performed. Thus, an expected signature value (which may be computed from the expected output value for a circuit) may be compared to an actual signature. For example, the expected output value 101010 may be converted to the signature 010101. This expected signature may then be compared with an actual signature generated from an actual output value—e.g., the signature 000101 from the actual output 111010. If these signatures match, it may be inferred that the logic under test is operating as designed. If these signatures do not match (e.g., expected signature 010101 vs. the actual signature 000101), it can be inferred that the logic is not operating as designed.

In various embodiments described below, the actual signatures may be generated by a multiple-input signature register (MISR) included in the BIST. As output values are generated, the MISR may capture the output values and generate a corresponding set of signatures. In various embodiments, the MISR may generate a given signature based on a current output value and a previously generated signature (or an initial seed value if no previous signature has been generated). Thus, a signature may be dependent on multiple output values. For example, the signature 010101 may be dependent on the five output values 111111, 111110, 000111, 110100, and 000101. As a result, a single comparison of signatures can be substituted for comparing multiple actual output values with their expected values.

In some instances, a logic built-in self-test (LBIST) unit may provide actual signatures generated by the MISR to automated test equipment (ATE) that compares those actual signatures with their expected signatures. A problem with this approach is that an ATE is typically testing several integrated circuits simultaneously and performing comparisons for each integrated circuit may be very time consuming since the ATE has only a limited amount of resources. To reduce the number of comparisons, an ATE may compare only the last signature produced for a set of output values with a corresponding expected signature. A problem with comparing only the last signature is that, if errors are detected, little diagnostic information can be discerned from the last signature. For example, in some instances, thousands of input values may be provided to a logic circuit to produce a signature. If that signature does not match its expected signature, it may not be possible to recover the mismatching output values from the signature or the input values that caused the incorrect output values. If developers want to identify these input values, input values may need to be retested individually. In many instances, such retesting is computationally expensive and may be more time consuming than the initial testing.

In various embodiments, the testing system described below includes an integrated circuit that uses a self-test unit configured to receive an expected signature from an external test tool (e.g., an ATE), and to compare the expected signature and an actual signature generated from one or more output values from the logic unit. The self-test unit may then indicate a result of the comparison to the external test tool. In some embodiments, the external test tool may be configured to generate a single set of expected signatures, and to provide that set to a plurality of integrated circuits (as opposed to generating a respective set of signatures for each circuit, which may be more computationally expensive). In some embodiments, the self-test unit may generate a respective signature for each input value provided to the logic unit and perform a respective comparison using that signature. Accordingly, if a generated signature does not match its corresponding expected signature but the previously generated signature produced a match, the input value associated with that signature can easily be identified as the one that produces an error.

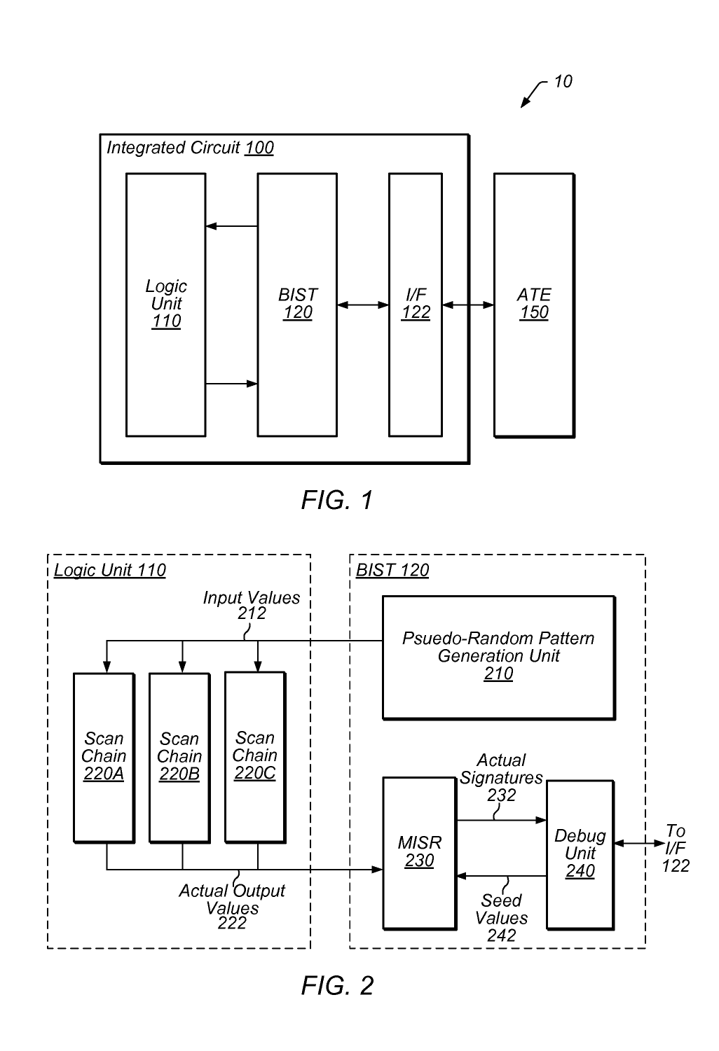

Turning now to FIG. 1, a block diagram of testing system 10 is depicted. Testing system 10 is one embodiment of a system for testing the integrity of integrated circuits. In the illustrated embodiment, system 10 includes an integrated circuit (IC) 100 that is coupled to automated test equipment (ATE) 150. IC 10 includes logic unit 110, built-in self-test (BIST) unit 120, and interface (I/F) 122.

IC 100 may be any type of integrated circuit that is suitable for testing. For example, in some embodiments, IC 100 is a processor, such as a central processing unit (CPU), a co-processor, an arithmetic processing unit, a graphics processing unit, a digital signal processor (DSP), etc. In some embodiments, IC 100 is a field-programmable gate array (FPGA). In some embodiments, IC 100 is an application-specific integrated circuit (ASIC).

Logic unit 110 may be any suitable circuitry in IC 100. In various embodiments, logic unit 110 is configured to receive one or more input values, and to perform one or more logical operations on the input values and using combinatorial logic such as AND gates, OR gates, etc. In some embodiments, logic unit 110 may be configured to store results of these operations in memory structures such as latches, flip-flops, etc. As noted above, the output values of logic unit 110 may be referred to as “actual output values.” In some embodiments, IC 100 may include multiple logical units 110 that are coupled to one BIST 120. In other embodiments, each logic unit 110 may be coupled to a respective BIST 120.

BIST 120 is one embodiment of a built-in self-test unit that is configured to test operation of logic unit 110. In one embodiment, BIST 120 is configured to generate one or more input values and to provide those values to logic unit 110. In some embodiments, BIST 120 is configured to generate the input values using a pseudo-random pattern generator that is initialized by ATE 150. In one embodiment, BIST 120 is configured to capture the corresponding output values produced by logic unit 110, and to determine whether the actual output values match the expected output values. In some embodiments, BIST 120 may be configured to determine whether matches exist by comparing the output values with expected output values for logic unit 110. In other embodiments, BIST 120 is configured to determine whether matches exist by comparing signatures generated from the actual output values (i.e., actual signature values) with signatures generated from the expected output values (i.e., expected signature values). BIST 120 may be configured to then provide the results of comparisons via interface 122 to ATE 150. If the actual output values match the expected output values, ATE 150 may be configured to indicate that logic unit 110 is operating as designed. On the other hand, if the actual output values do not match the expected output values, ATE 150 may be configured to indicate that logic unit 110 is faulty. By performing comparisons locally, BIST 120 may improve the utilization of ATE 150 by reducing the usage of its limited resources, and thus reduce testing time and costs.

In one embodiment, BIST 120 is configured to generate actual signatures from actual output values that it captures, and to receive expected signatures values via interface 122 from ATE 150. In one embodiment, BIST 120 is configured to generate a given signature based on a current output value and either a previous signature (or an initial seed value if the given signature is an initial signature). For example, BIST 120 may provide N input values to logic unit 110 and receive N corresponding output values. For an initial one of the N output values, BIST 120 may generate an initial signature based on this output value and a provided initial seed value. Subsequent signatures may then be generated based on a previous signature and a current output value (i.e., the output value most recently captured from logic unit 110.) Because each subsequent signature is dependent on a previous signature, each subsequent signature is dependent on not only a current output value but also any previous output values. Thus, the last generated signature is dependent on all input values provided to logic unit 110. If a signature is dependent on an actual output value that does not match an expected output value, that actual signature does not match the expected signature for the N input values.

In one embodiment, BIST 120 may be configured to compare only the last actual signature and its corresponding expected signature. (As noted above, if these signatures do not match, identifying input values that produced the faulty signature may require extensive retesting). In other embodiments, BIST 120 is configured to generate a respective signature for each actual output value, and to compare that actual signature with a corresponding expected signature received from ATE 150. BIST 120 may be configured to then indicate the results of each comparison to ATE 150. If a given signature does not match its corresponding expected signature and its previous signature matched its corresponding expected signature, ATE 150, in one embodiment, may be configured to not only indicate that an actual signature did not match the expected signature, but also identify the input value that created the incorrect output value. In some instances, identifying input values without having to perform retesting reduces overall testing time, and thus may reduce costs and improve manufacturing yield.

Interface 122, in one embodiment, is a test access port (TAP) controller that is configured to facilitate communication between BIST 120 and ATE 150. In some embodiments, interface 122 is configured to implement a version of the IEEE 1149.1 standard (also known as the Joint Test Action Group (JTAG) standard). In one embodiment, interface 122 is configured to transmit commands from ATE 150 to BIST 120 (e.g., to enable or disable various functionality of BIST 120, to perform various tests, etc.). In various embodiments, interface 122 is further configured to exchange information to facilitate testing such as initial seed values, signatures, comparison results, etc. In some embodiments, interface 122 may be considered as being part of BIST 120.

ATE 150 is one embodiment of an external test tool that is configured to test the integrity of integrated circuits using built-in self-test units such as BIST 120. In various embodiments, ATE 150 may be configured to provide commands and information that are usable by BIST 120 to facilitate testing of logic unit 110. In some embodiments, ATE 150 may be configured to instruct BIST 120 to provide a specified number of input values to logic unit 110, and to provide a seed value that is usable to generate the input values. In one embodiment, as BIST 120 generates signatures, ATE 150 is configured to provide expected signatures to BIST 120 for comparisons with the actual signatures. In some embodiments, ATE 150 is configured to provide only an expected signature corresponding to the last generated signature. In other embodiments, ATE 150 is configured to provide a respective signature for each actual signature generated by BIST 120. In some embodiments, ATE 150 is configured to determine signatures based on the seed value and the number of input values that have been generated by BIST 120. In one embodiment, ATE 150 is configured to analyze results of comparisons provided by BIST 120. As noted above, in some embodiments, ATE 150 is configured to indicate whether any actual signatures do not match corresponding expected signatures, and to identify the input values that caused the mismatches. In some instances, diagnostic tools may use this information to identify specific defective logic in logic unit 110 and to adjust discrepancies in the manufacturing process of IC 100.

In various embodiments, ATE 150 is configured to provide the same commands and information to multiple BISTs 120 located on separate ICs 100. For example, in one embodiment, ATE 150 may be configured to provide the same initial seed value to pseudo random pattern generators on the BISTs 120 to cause them to produce the same inputs values. ATE 150 may be configured to then provide the same expected signatures to each BIST 120. By providing the same commands and information to each BIST 120, ATE 150, in many instances, may be more efficiently utilized.

Logic unit 110 and BIST 120 are described in further detail next in conjunction with FIG. 2.

Turning now to FIG. 2, a block diagram of logic unit 110 and BIST 120 is depicted. In the illustrated embodiment, logic unit 110 includes scan chains 220A-220C. BIST 120 includes pseudo-random pattern generation unit 210, multiple-input signature register (MISR) 230, and debug unit 240.

Pseudo-random pattern generation unit 210, in one embodiment, is configured to generate input values 212 for scan chains 220. In one embodiment, generation unit 210 is configured to generate a random pattern of bits using one or more linear feedback shift registers (LFSRs). In one embodiment, generation unit 210 is configured to initialize an LFSR with a seed value, and to provide a clock signal to the LFSR. As the clock signal changes, the LFSR may be configured to generate new bits by performing logical operations on bits stored in the LFSR. In some embodiments, generation unit 210 is configured to initialize an LFSR using a seed value provided by ATE 150. In other embodiments, generation unit 210 is configured to initialize an LFSR using a seed value stored in BIST 120, e.g., during fabrication.

Scan chains 220, in one embodiment, are paths within logic unit 120 that are configured to perform one or more logical operations to produce actual output values 222. In one embodiment, each scan chain 220 may include one or more input pins that are coupled to flip-flops configured to store bits generated by generation unit 210 for processing in that chain 220. As corresponding output values 222 are generated, each scan chain 220 may also include one or more output pins that are coupled to flip-flops that are configured to store bits of the output values 222. In one embodiment, MISR 230 is configured to capture the output values 222 by reading the bits stored in the flip-flops.

MISR 230, in one embodiment, is configured to generate actual signatures 232 based on actual output values 222 of scan chains 220. In one embodiment, MISR 230 may be configured to read bits from each scan chain during one or more clock cycles. MISR 230 may be configured to then apply a signature function on those bits and bits associated with a previously generated signature to produce a new signature. In some embodiments, MISR 230 may be configured to use a signature that it generated as this previous signature. In other embodiments, MISR 230 may be configured to use seed values 242 provided by ATE 150 (e.g., via debug unit 240) that are the expected signatures of previously generated signature 232.

Debug unit 240, in one embodiment, is configured to compare actual signatures 232 generated by MISR 230 with expected signatures received from ATE 150 via interface 122. In various embodiments, debug unit 240 is configured to receive an expected signature while an actual signature 232 is being generated in parallel. That is, there may be an overlap between the period in which an actual signature 232 is generated and the period in which debug unit 240 receives an expected signature. For example, in some instances, debug unit 240 may receive an expected signature as scan chains 220 are concurrently creating an actual output value 222 for the actual signature 232. Debut unit 240 may also receive an expected signature when MISR 230 is generating an actual signature 232. In one embodiment, if MISR 230 completes generation of an actual signature 232 before debug unit 240 has received a corresponding expected signature, debug unit 240 may be configured to delay generation of subsequent actual signatures 232. On the other hand, if debug unit 240 receives an expected signature before an actual signature 232 has been generated, debug unit 240, in one embodiment, may be configured to instruct ATE 150 via interface 122 to delay sending subsequent expected signatures.

In one embodiment, Debug unit 240 is further configured to provide the results of comparisons to ATE 150 via interface 122. In various embodiments, debug unit 240 is configured to represent a result of a given comparison as a pattern of bits that are set to indicate whether corresponding bits in an actual signature 232 matched the bits in an expected signature. For example, an actual signature 232 and an expected signature may include the bits 0010 and 1010 respectively. After comparing these signatures, debug unit 240, in one embodiment, may generate a result that includes the bits 1000, where the initial 1 indicates a mismatch (alternatively, mismatches may be represented by 0). Thus, in some embodiments, debug unit 240 may be configured to indicate that two signatures match by outputting a consistent pattern of bits (e.g., a sequence of all zeros or a sequence of all ones).

In one embodiment, debug unit 240 is further configured to provide a received expected signature to MISR 230 as a seed value 242 for use in generating the next signature 232. In some embodiments, debug unit 240 may be configured to provide an expected signature for each signature 232 being generated by MISR 230. In other embodiments, debug unit 240 may be configured to provide an expected signature for only a subset of signatures 232 generated by MISR 230. In various embodiments, debug unit 240 may be configured to provide an expected signature to MISR 230 while simultaneously performing a comparison using that signature, so that a new signature 232 may be available upon completion of the comparison.

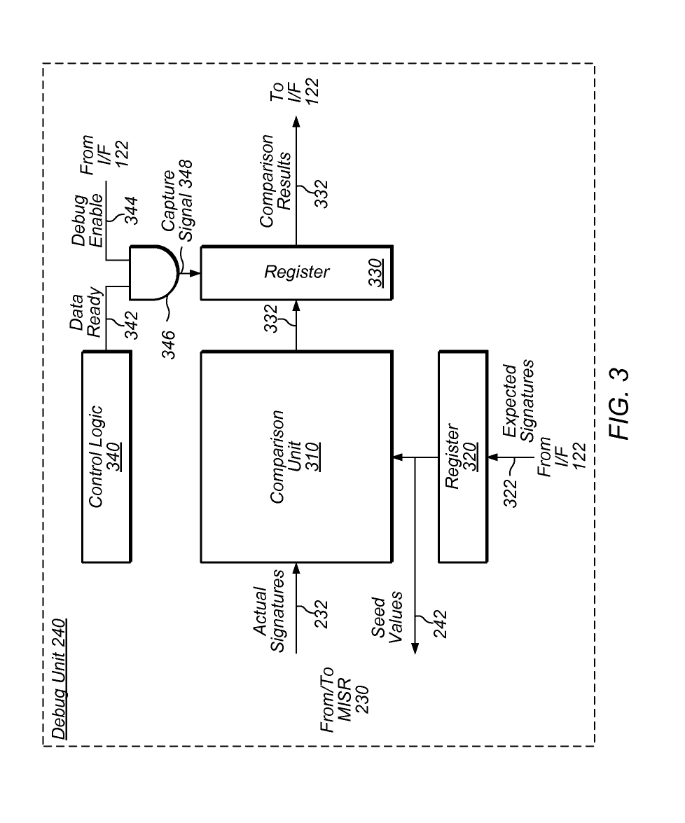

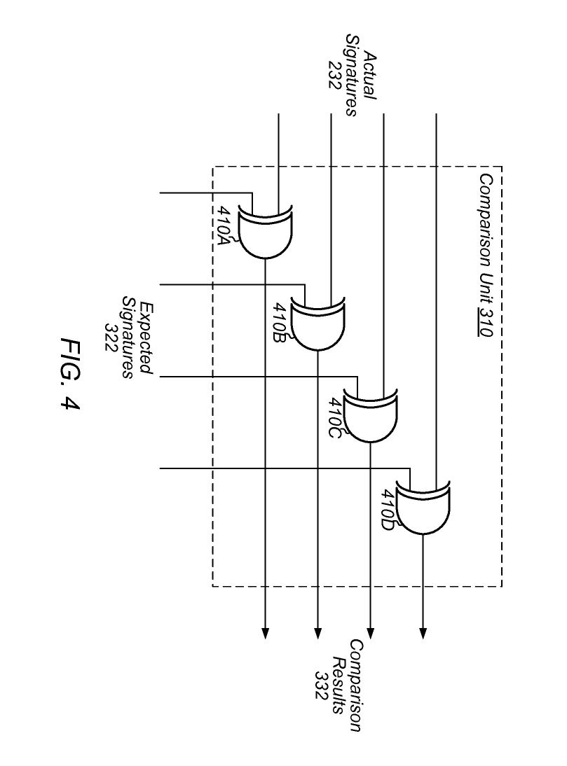

Turning now to FIG. 3, a block diagram of debug unit 240 is depicted. As discussed above, in one embodiment, debug unit 240 is configured to perform comparisons between actual signatures (e.g., actual signatures 232) and expected signatures (e.g., expected signatures 322). In some embodiments, debug unit 214 is also configured to provide the expected signatures (e.g., as seed values 242) to MISR 230 for use in generating subsequent actual signatures. In the illustrated embodiment, debug unit 240 includes comparison unit 310, register 320, register 330, and control logic 340. (In some embodiments, debug unit 240 may alternatively include a single register that performs operations of both registers 320 and 330.)

Comparison unit 310, in one embodiment, is configured to compare actual signatures 232 generated by MISR 230 with expected signatures 322 received from ATE 150 via interface 122. In illustrated embodiment, comparison unit 310 is further configured to provide comparison results 332 to ATE 150 via interface 122. In some embodiments, comparison unit 310 is configured to compare actual signatures with expected signatures 322, by performing a bitwise exclusive OR (as referred to as an XOR) operation of signatures 232 and 322. Comparison unit 310 is described in further detail below in conjunction with FIG. 4.

Register 320, in one embodiment, is configured to store expected signatures 322 received from ATE 150 prior to being compared. As MISR 230 generates actual signatures 232, register 320, in one embodiment, is configured to then provide the corresponding signatures 322 to comparison unit 310. In one embodiment, register 320 is further configured to provide expected signatures 322 as seed values 242 to MISR 230 for use in generating subsequent signatures 232. In some embodiments, register 320 is configured to provide a given signature 322 to comparison unit 310 and MISR 230 simultaneously. In some embodiments, register 320 is configured to provide an indication to control logic 340 specifying when register 320 has received a new signature from ATE 150. Such an indication may then be used to coordinate operations of debug unit 240.

Register 330, in one embodiment is configured to capture and store comparison results 332 generated by comparison unit 310. In one embodiment, register 330 is further configured to provide results to ATE 150. In one embodiment, register 330 is configured to capture comparison results 332 upon control logic 340 asserting capture signal 348 (described below).

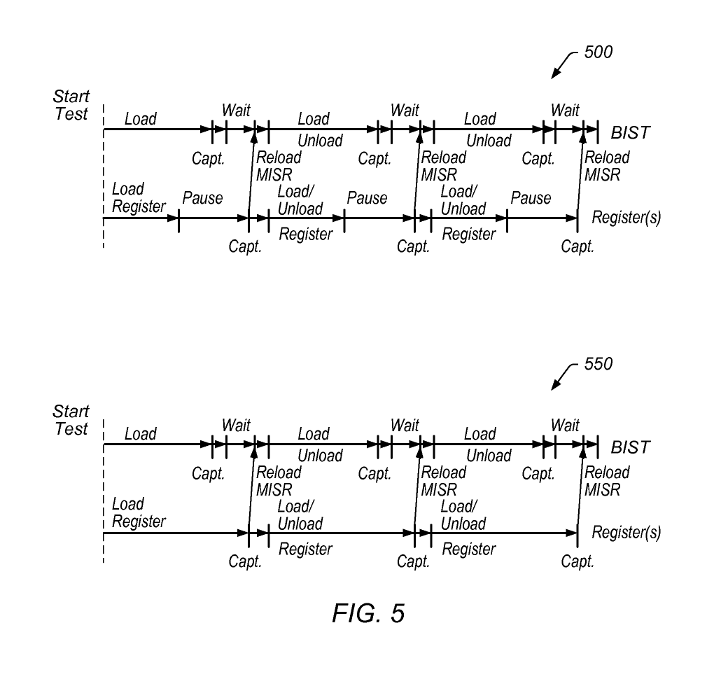

Control logic 340, in one embodiment, is configured to coordinate operation of debug unit 240. In various embodiments, control logic 340 may include circuitry configured to implement one or more state machines used by logic 340. In one embodiment, control logic 340 is configured to coordinate the capturing of comparisons results 332 in conjunction with the generation of actual signatures 232 and the receiving of expected signatures 322. To coordinate these operations, control logic 340, in one embodiment, is configured to determine if signatures 232 and 322 are ready for comparison (i.e., an actual signature has been generated and an expected signature value has been received), and to assert a data ready signal 342 to cause register 330 to capture the output of comparison unit 310. In the illustrated embodiment, AND gate 346 is configured to perform an AND operation of data ready signal 342 and a debug enable signal 344 that is asserted if BIST 120 is being used in debug mode (i.e., BIST 120 is using debug unit 240 to test IC 100; in some embodiments, BIST 120 may be used without using debug unit 240). In some embodiments, control logic 340 may also be configured to coordinate other operations of BIST 120 such as those associated with loading and unloading scan chains 220. Exemplary timing diagrams illustrating the coordination of various operations are described below in conjunction with FIG. 5.

Turning now to FIG. 4, a block diagram of comparison unit 310 is depicted. In the illustrated embodiment, comparison unit 310 includes a plurality of exclusive-OR gates 410A-D that are each configured to perform a bitwise exclusive-OR operation of a bit of an actual signature 232 and a bit of an expected signature 322 to produce a bit in a result 332. Accordingly, if all of the bits in signatures 232 and 322 match, gates 410 are configured to output a consistent pattern of bits (e.g., all zeros). On the other hand, if certain bits do not match, gates 410, in one embodiment, are configured to output a respective logical one in a result 332 for each of those bits. As discussed above, diagnostic tools may analyze bits of results 332 to identify input values 212 that produced those results 332. (It is noted that, in other embodiment, comparison unit 310 may compare signatures 232 and 322 using other suitable techniques.)

Turning now to FIG. 5, two exemplary timing diagrams 500 and 550 are depicted. Timing diagrams 500 and 550 illustrate one embodiment of timing characteristics for generating actual signatures 232 and receiving expected signatures 322. As noted above, control logic 340 may be configured to coordinate the capturing of comparisons results 332 in conjunction with these operations to ensure that both signatures 232 and 322 are ready for comparison and that results 332 will be correctly captured.

In some embodiments, the timing of the generation of a signature 232 and the receiving of a corresponding signature 322 may occur asynchronously. For example, the time taken to generate signatures 232 may depend on the time taken by BIST 120 for loading and unloading of values from logic unit 110, which may depend on scan chain length (e.g., the number of scan flops in scan chains 220) and scan shift speed. The time taken to receive signatures 322 may depend on the loading and unloading time of register 330, which may depend on the width of register 330. The time taken to receive signatures 322 may also depend on other factors such as the transfer rate of interface 122 and operation of ATE 150.

To enable the synchronization between the two operations, control logic 340, in one embodiment, may include a state machine that implements a wait state and a capture state. In the wait state, control logic 340 may be configured to wait for a signal from register 330 indicating that it has finished loading an expected signature 322. Once this signal is received, control logic 340 may be configured to transition to the capture state, in which control logic 340 is configured to instruct register 330 to capture the output of comparison unit 310. In one embodiment, control logic 340 may also be configured to simultaneously cause MISR 230 be re-loaded with the expected signature 322 in register 330. After completion of the capturing and the re-loading, control logic 340 may move on to the next pair of signatures.

Exemplary timing diagram 500 is one embodiment of a timing diagram that illustrates when a signature 322 is received by register 320 before a signature 232 is generated. In one embodiment, when the loading of register 320 completes early, ATE 150 may be “paused” (e.g., control logic 340 may instruct ATE 150 via interface 122 to transition to a wait state) until enough time has elapsed for the generation of a signature 232 to complete. In some instances, the amount of “pause” can be arbitrarily large with no impact other than increasing debug time. For example, in one embodiment, if JTAG is used to load register 320, a user may instruct ATE 150 to pause in the TAP Run-Test-Idle state. The synchronization signal may be enabled once the user has traversed through the Update-DR TAP state. In one embodiment, control logic 340 may be configured to cause register 330 to capture the difference in signatures 232 and 322 during the Capture-DR TAP state. In some embodiments, pausing ATE 150 in this manner when capturing results 332 may remove a hand shaking between ATE 150 and BIST 120.

Exemplary timing diagram 550 is one embodiment of a timing diagram that illustrates when the loading of register 320 is completed after generating of a signature 232. In the case when the loading of register 320 completes afterwards, control logic 340, in one embodiment, is configured to transition to a wait state after an actual signature 232 is generated. The synchronization may be automatic when register 320 is completely loaded and a signal is sent (e.g., from register 320) to control logic 340 to resume.

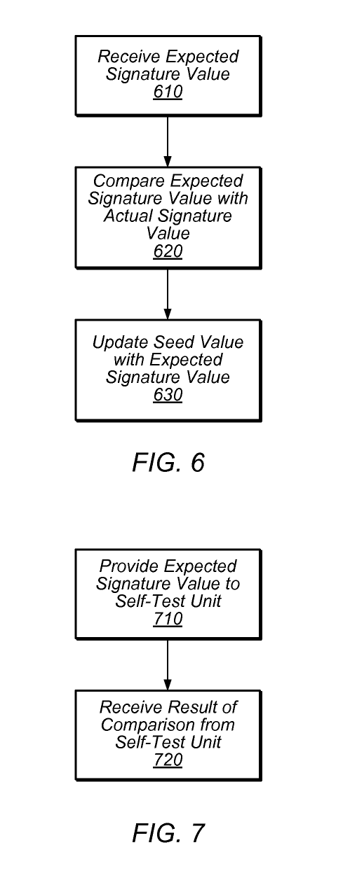

Turning now to FIG. 6, a flow diagram of a method 600 is depicted. Method 600 is one embodiment of a method that may be performed by an integrated circuit that includes a built-in self-test unit such as IC 100. In some instances, performing method 600 may reduce testing time and improve manufacturing yield.

In step 610, IC 100 (e.g., using BIST 120) receives an expected signature value (e.g., expected signature 322) that corresponds to an expected output value of a logic unit (e.g., logic unit 110). In one embodiment, the expected signature value is received from an external test tool (e.g. ATE 150) via a test access port (e.g., interface 122). In one embodiment, the expected output value corresponds to one of a plurality of input values (e.g., input values 212) generated by a pseudo-random pattern generator (e.g., pseudo-random pattern generation unit 210) to cause the logic unit to generate a plurality of actual output values (e.g., actual output values 222). In some embodiments, a self-test unit of IC 100 (e.g., BIST 120) generates a respective actual signature value for each actual output value, and compares each actual signature value with a corresponding expected signature value received from the external test tool. In one embodiment, the self-test unit receives an expected signature while an actual signature is being generated (i.e., the unit receives the expected signature concurrently with the generation of the actual signature). In some embodiments, the self-test unit may compare only the last generated actual signature value with its corresponding expected signature. In one embodiment, the external test tool provides the same expected signature values to a plurality of self-test units located in separate ICs 100.

In step 620, IC 100 compares the expected signature value with an actual signature value (e.g., actual signature 232) generated from an actual output value of the logic unit. In one embodiment, the actual signature value is generated by a multiple-input signature register (e.g., MISR 230) based on the actual output value and a seed value (e.g., seed value 242). In some embodiments, the seed value is an expected signature value received from the external test tool and corresponds to a previous expected output value. In some embodiments, IC 100 performs the comparison by performing a bitwise exclusive-OR operation (e.g., using exclusive-OR gates 410) of the expected signature value and the actual signature value. Then, IC 100 may provide a result of the bitwise exclusive-OR operation to the external test tool. In some embodiments, a register (e.g., register 330) of IC 100 stores the result prior to the result being provided to the external test tool, and the self-test unit instructs the register to store the result in response to determining that the actual signature value has been generated and the expected signature value has been received. In some embodiments, if the expected signature value matches the actual signature value, the result is a consistent pattern of bits (e.g., a sequence of all zeros).

In step 630, IC 100 updates the seed value used to generate a subsequent actual signature value with the received expected signature values. In one embodiment, a multiple-input signature register (e.g., MISR 230) uses the updated seed value and a subsequent output value to generate the next actual signature value that is to be compared. In various embodiments, step 630 may be performed concurrently with step 620. For example, in one embodiment, a register (e.g., register 320) that stores the received expected signature value may simultaneously provide that value to a comparison unit (e.g., comparison unit 310) used in step 620 and the MISR. (In some embodiments, method 600 may be performed without performing step 630.)

Turning now to FIG. 7, a flow diagram of a method 700 is depicted. Method 700 is one embodiment of a method that may be performed by an external test tool, such as ATE 150, to test an integrated circuit, such as IC 100. In some instances, performing method 700 may improve utilization of the external test tool and reduce testing time.

In step 710, ATE 150 provides an expected signature value (e.g., expected signature 322) to a self-test unit (e.g., BIST 120) on an integrated circuit. The expected signature value may correspond to an expected output value of a logic unit (e.g., logic unit 110) on the integrated circuit. In one embodiment, the self-test unit performs a comparison of the expected signature value with an actual signature value (e.g., actual signature 232) generated from an actual output value (e.g., actual output value 222) of the logic unit. In some embodiments, the self-test unit includes a multiple-input signature register (e.g., MISR 230) configured to generate the actual signature value based on the actual output value and a first seed value (e.g., seed value 242) that corresponds to a previous signature. The MISR may then use the provided expected signature value as a second seed value to generate a subsequent actual signature value. In some embodiments, ATE 150 also provides the expected signature value to other self-test units on other integrated circuits. In various embodiments, the ATE 150 communicates with the self-test units via a Joint Test Action Group (JTAG) standard.

In step 720, ATE 150 receives a result of the comparison (e.g., comparison result 332) from the self-test unit. In one embodiment, ATE 150 indicates that the logic unit produced an error in response to determining that the result is not a consistent pattern of bits. In some embodiments, ATE 150 also uses the result to identify a defective operation (e.g., associated with an input value 212) of the logic unit that caused production of the error. In some embodiments, ATE 150 may receive results of comparisons from other self-test units that also used the expected signature value.

Exemplary Computer System

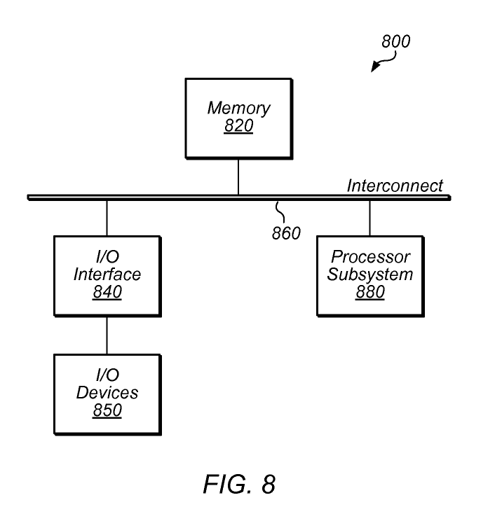

Turning now to FIG. 8, one embodiment of an exemplary computer system 800, which may include integrated circuit 100, is depicted. Computer system 800 includes a processor subsystem 880 that is coupled to a system memory 820 and I/O interfaces(s) 840 via an interconnect 860 (e.g., a system bus). I/O interface(s) 840 is coupled to one or more I/O devices 850. Computer system 800 may be any of various types of devices, including, but not limited to, a server system, personal computer system, desktop computer, laptop or notebook computer, mainframe computer system, handheld computer, workstation, network computer, a consumer device such as a mobile phone, pager, or personal data assistant (PDA). Computer system 800 may also be any type of networked peripheral device such as storage devices, switches, modems, routers, etc. Although a single computer system 800 is shown for convenience, system 800 may also be implemented as two or more computer systems operating together.

Processor subsystem 880 may include one or more processors or processing units. For example, processor subsystem 880 may include one or more processing units (each of which may have multiple processing elements or cores) that are coupled to one or more resource control processing elements 820. In various embodiments of computer system 800, multiple instances of processor subsystem 880 may be coupled to interconnect 860. In various embodiments, processor subsystem 880 (or each processor unit or processing element within 880) may contain a cache or other form of on-board memory. In one embodiment, processor subsystem 880 may include integrated circuit 100 described above.

System memory 820 is usable by processor subsystem 880. System memory 820 may be implemented using different physical memory media, such as hard disk storage, floppy disk storage, removable disk storage, flash memory, random access memory (RAM—SRAM, EDO RAM, SDRAM, DDR SDRAM, RAMBUS RAM, etc.), read only memory (PROM, EEPROM, etc.), and so on. Memory in computer system 800 is not limited to primary storage such as memory 820. Rather, computer system 800 may also include other forms of storage such as cache memory in processor subsystem 880 and secondary storage on I/O Devices 850 (e.g., a hard drive, storage array, etc.). In some embodiments, these other forms of storage may also store program instructions executable by processor subsystem 880.

I/O interfaces 840 may be any of various types of interfaces configured to couple to and communicate with other devices, according to various embodiments. In one embodiment, I/O interface 840 is a bridge chip (e.g., Southbridge) from a front-side to one or more back-side buses. I/O interfaces 840 may be coupled to one or more I/O devices 850 via one or more corresponding buses or other interfaces. Examples of I/O devices include storage devices (hard drive, optical drive, removable flash drive, storage array, SAN, or their associated controller), network interface devices (e.g., to a local or wide-area network), or other devices (e.g., graphics, user interface devices, etc.). In one embodiment, computer system 800 is coupled to a network via a network interface device.

Program instructions that are executed by computer systems (e.g., computer system 800) may be stored on various forms of computer readable storage media. Generally speaking, a computer readable storage medium may include any non-transitory/tangible storage media readable by a computer to provide instructions and/or data to the computer. For example, a computer readable storage medium may include storage media such as magnetic or optical media, e.g., disk (fixed or removable), tape, CD-ROM, or DVD-ROM, CD-R, CD-RW, DVD-R, DVD-RW, or Blu-Ray. Storage media may further include volatile or non-volatile memory media such as RAM (e.g. synchronous dynamic RAM (SDRAM), double data rate (DDR, DDR2, DDR3, etc.) SDRAM, low-power DDR (LPDDR2, etc.) SDRAM, Rambus DRAM (RDRAM), static RAM (SRAM), etc.), ROM, Flash memory, non-volatile memory (e.g. Flash memory) accessible via a peripheral interface such as the Universal Serial Bus (USB) interface, etc. Storage media may include microelectromechanical systems (MEMS), as well as storage media accessible via a communication medium such as a network and/or a wireless link.

In some embodiments, a computer-readable storage medium can be used to store instructions read by a program and used, directly or indirectly, to fabricate hardware for integrated circuit 100 described above. For example, the instructions may outline one or more data structures describing a behavioral-level or register-transfer level (RTL) description of the hardware functionality in a high level design language (HDL) such as Verilog or VHDL. The description may be read by a synthesis tool, which may synthesize the description to produce a netlist. The netlist may comprise a set of gates (e.g., defined in a synthesis library), which represent the functionality of integrated circuit 100. The netlist may then be placed and routed to produce a data set describing geometric shapes to be applied to masks. The masks may then be used in various semiconductor fabrication steps to produce a semiconductor circuit or circuits corresponding to integrated circuit 100.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. An integrated circuit, comprising:
a logic unit; and
a self-test unit configured to receive, from a test tool external to the integrated circuit, an expected signature value that corresponds to an expected output value of the logic unit, and wherein the self-test unit is further configured to compare the expected signature value with an actual signature value generated from an actual output value of the logic unit.

2. The integrated circuit of claim 1, further comprising:
a multiple-input signature register (MISR) configured to generate the actual signature value based on the actual output value and a seed value.

3. The integrated circuit of claim 2, wherein the self-test unit is configured to receive the seed value from the external test tool, and wherein the seed value is an expected signature value corresponding to a previous expected output value.

4. The integrated circuit of claim 1, further comprising:
a pseudo-random pattern generator configured to provide an input value to the logic unit, wherein the logic unit is configured to generate the actual output value based on the provided input value.

5. The integrated circuit of claim 1, wherein the self-test unit is configured to:
provide a plurality of input values to the logic unit to cause the logic unit to generate a plurality of actual output values;
generate a respective actual signature value for each actual output value; and
compare each actual signature value with a corresponding expected signature value.

6. The integrated circuit of claim 1, wherein the self-test unit includes a comparison unit configured to perform a bitwise exclusive-OR operation of the expected signature value and the actual signature value to produce a result of the exclusive-OR operation.

7. The integrated circuit of claim 6, further comprises:
a register configured to store the result of the bitwise exclusive-OR operation prior to the self-test unit providing the result to the external test tool, and wherein the self-test unit is configured to instruct the register to store the result in response to determining that the actual signature value has been generated and the expected signature value has been received.

8. The integrated circuit of claim 6, wherein the comparison unit is configured to output a consistent pattern of bits in response to the expected signature value matching the actual signature value.

9. The integrated circuit of claim 1, wherein the self-test unit is configured to receive the expected signature value concurrently with generation of the actual signature value.

10. A computer readable storage medium having program instructions stored thereon that are executable by a computer system to cause the computer system to perform:
providing an expected signature value to a self-test unit on an integrated circuit, wherein the expected signature value corresponds to an expected output value of a logic unit on the integrated circuit, and wherein the self-test unit is configured to perform a comparison of the expected signature value with an actual signature value generated from an actual output value of the logic unit; and
receiving a result of the comparison from the self-test unit.

11. The computer readable storage medium of claim 10, wherein the self-test unit includes a multiple-input signature register (MISR) configured to generate the actual signature value based on the actual output value and a first seed value, and wherein the MISR is configured to use the provided expected signature value as a second seed value to generate a subsequent actual signature value.

12. The computer readable storage medium of claim 10, wherein the program instructions are further executable to cause the computer system to perform:
determination of whether the result is a consistent pattern of bits; and
in response to determining that the result is not a consistent pattern of bits, indicating that the logic unit produced an error.

13. The computer readable storage medium of claim 12, wherein the program instructions are further executable to cause the computer system to perform:
using the result to identify a defective operation of the logic unit that caused production of the error.

14. The computer readable storage medium of claim 10, wherein the program instructions are further executable to perform:
providing the expected signature value to a plurality of self-test units on a plurality of different integrated circuits; and
receiving results of comparisons from the plurality of self-test units.

15. The computer readable storage medium of claim 10, wherein the computer system is configured to communicate with the self-test unit via a Joint Test Action Group (JTAG) standard.

16. A method, comprising:
a test unit in an integrated circuit receiving an expected signature value from a test tool external to the integrated circuit, wherein the expected signature value corresponds to an expected output value of a logic unit in the integrated circuit;
the test unit comparing the expected signature value with a first actual signature value generated from an actual output value of the logic unit;
the test unit providing a result of the comparison to the external test tool.

17. The method of claim 16, further comprising:
the test unit using the expected signature value as a seed value to generate a second actual signature value based on the subsequent actual output value.

18. The method of claim 16, wherein the result is a consistent pattern of bits if the logic unit does not produce an error in response to a received input.

19. The method of claim 16, wherein the received expected signature value is provided to other test units in other integrated circuits that are configured to perform comparisons using the expected signature value.

20. The method of claim 16, wherein the receiving of the expected signature occurs while the first actual signature value is being generated.

21. A computer readable storage medium comprising a data structure which is operated upon by a program executable on a computer system, the program operating on the data structure to perform a portion of a process to fabricate an integrated circuit including circuitry described by the data structure, the circuitry described by the data structure including:
a self-test unit configured to receive an expected signature value that corresponds to an expected output value of a logic unit in the integrated circuit, wherein the self-test unit is further configured to compare the expected signature value with an actual signature value generated from an actual output value of the logic unit.

22. The computer readable storage medium of 21, wherein the storage medium stores hardware description language (HDL) data, Verilog data, or graphic database system II (GDSII) data.
